(19) United States
(12) Patent Application Publication
(10) Pub. No.: US 2002/0060064 A1
(43) Pub. Date: May 23, 2002

(54) Heat sink assembly

(76) Inventor: Hung-Chi Yu, Hsi-Chih (TW)

Correspondence Address: Wei Te (Joseph) Chung, Foxconn International, Inc., 1650 Memorex Drive, Santa Clara, CA, 95050, US

(21) Appl. No.: 09/749,031

(22) Filed: Dec. 26, 2000

(30) Foreign Application Priority Data
Nov. 17, 2000 (TW) 89219995

(51) Int. Cl. F28F 7/00; H05K 7/20; H01L 23/34

(52) U.S. Cl. 165/80.3; 165/185; 257/719; 361/704; 174/16.3

(57) ABSTRACT

A heat sink assembly (1) includes a rectangular socket (30) on which a chip unit (4) is mounted. A pair of mounting portions (31) neighbor two lateral sides of the socket. Each mounting portion has at least a protrusion (313) on each of two opposite first sides (311) of the mounting portion and a bulge (314) on a second side (312) between the first sides. A heat sink (2) is attached on the chip unit. The heat sink has a horizontal base (20) and a plurality of heat dissipating fins (21) vertically upwardly from the base. The heat sink further has a mounting flange (22) located beside the fins. An elongated clip (32) has two ends fitted with the protrusions and a retaining section (326) receiving the bulge. The retaining section has a lower arm (3231) fixedly engaging with the bulge. A bolt (33) screws through the clip and depresses the heat sink.

### BACKGROUND OF THE INVENTION

1. Field of the Invention

The present invention relates to a heat sink assembly, and particularly to a heat sink assembly used for dissipating heat generated by a central processing unit mounted on a socket.

2. Description of Prior Art

Heat produced by a chip unit during operation thereof needs to be timely dissipated to ensure a proper operation of the chip unit. To achieve this, a heat sink assembly is generally used. U.S. Pat. No. 5,671,118 discloses socket forming two opposite claws, a chip unit mounted on the socket, a heat sink positioned on the chip unit and a two-piece clip having two end portions respectively engaging with the claws and a spring section exerting a pressing force on the heat sink toward the chip unit to cause the heat sink and the chip unit to have an intimate contact whereby the heat sink can absorb heat generated by the chip unit to timely dissipate the heat generated by the chip unit during operation thereof.

However, the prior art clip can not be securely fixed to the socket; thus, when subject to vibration of shock, the clip may separate from the socket, which causes the heat sink to no longer have an intimate engagement with the chip unit, and the heat generated by the chip unit can not be timely dissipated.

Hence, an improved heat sink assembly is required to overcome the disadvantages of the conventional heat sink assembly.

### SUMMARY OF THE INVENTION

Accordingly, a main object of the present invention is to provide a heat sink assembly having clips which can be securely fixed to a socket so that an intimate engagement between a chip unit and a heat sink can be always ensured even when the heat sink assembly is under vibration or shock.

In order to achieve the object set forth, a heat sink assembly includes a rectangular socket on which a chip unit is mounted. A pair of mounting portions neighbor two lateral sides of the socket respectively. Each mounting portion has at least a protrusion on each of two opposite first sides of the mounting portion and a bulge on a second side between the first sides. A heat sink is attached on the chip unit. The heat sink has a horizontal base and a plurality of heat dissipating fins vertically upwardly from the base. The heat sinkfurther has a pair of mounting flanges located beside the fins, respectively. An elongated clip has two ends fitted with the protrusions and a retaining section receiving the bulge. The retaining section has a lower arm fixedly engaging with the bulge. A bolt or vertically moveable pole, screws or extends through the clip and depresses the heat sink at a position near the retaining section.

Other objects, advantages and novel features of the invention will become more apparent from the following detailed description when taken in conjunction with the accompanying drawings.

### BRIEF DESCRIPTION OF THE DRAWINGS

FIG. 1 is an exploded perspective view of a heat sink assembly in accordance with a first embodiment of the present invention and a chip unit;

FIG. 2 is a perspective view of the heat sink assembly of FIG. 1 wherein bolts have not assembled into the screw holes of clips of the assembly;

FIG. 3 is a perspective view of the heat sink assembly; and

FIG. 4 is an exploded perspective view of a heat sink assembly in accordance with an alternative embodiment of the present invention and a chip unit.

### DETAILED DESCRIPTION OF PREFERRED EMBODIMENTS

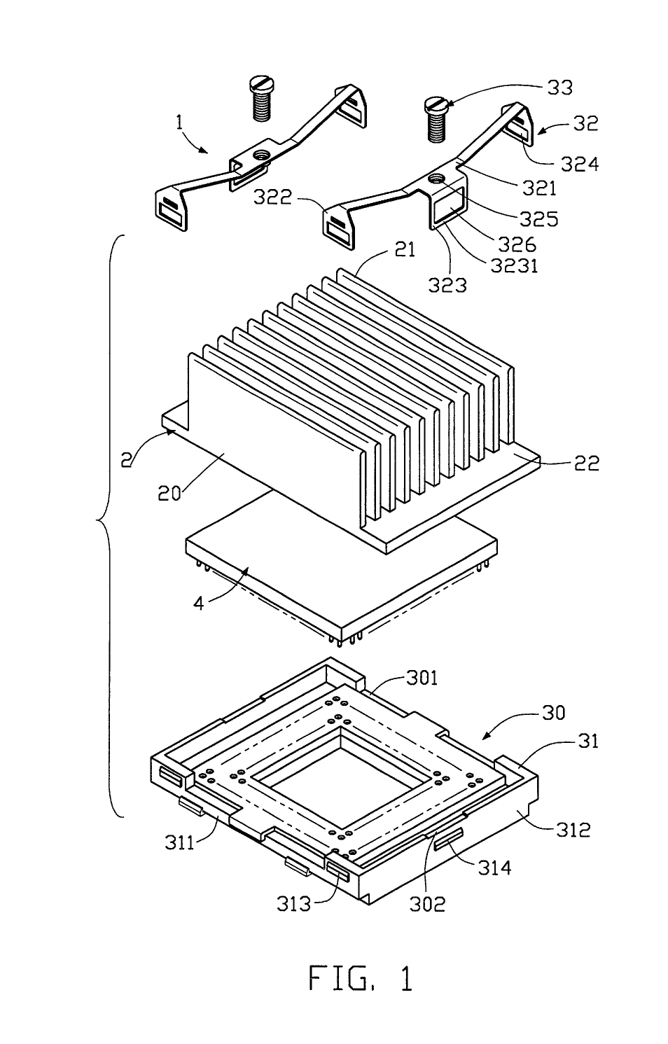

Referring to FIG. 1, a heat sink assembly 1 includes a heat sink 2, a pair of clips 32, a pair of bolts 33 and a socket 30. The heat sink 2 includes a plurality of upward cooling fins 21 and a pair of mounting flanges 22 extending outward from a base 20 of the heat sink 2 beside the cooling fins 21, respectively.

The socket 30 is used for electrically connecting a chip unit 4 to a print circuit board (not shown) such as a mother board, which is well known by those skilled in the art. Therefore, a detailed description regarding this is omitted here. The socket 30 comprises a pair of opposite mounting portions 31 on lateral sides thereof, respectively, and four upwardly extending sidewalls. Two slots 301 are respectively defined in two opposite sidewalls which are parallel to an extending direction of the cooling fins 21, while two grooves 302 are respectively defined in the other two opposite sidewalls. Each of the sidewalls wherein the slots 301 are formed has two outwardly extended protrusions 313 located on the mounting portions 31, respectively. Each of the sidewalls wherein the grooves 302 are defined has an outwardly extended bulge 314 thereon. The bulge 314 is located just below a corresponding groove 302.

Each clip 32 has an elongated configuration and comprises two first retaining sections 322 at two ends thereof and a pressing section 321 in a middle thereof. A second retaining section 323 is formed downwardly extending from an outer side of the middle of the clip 32. The first and second retaining sections 322, 323 each have a substantially rectangular configuration and define a rectangular hole 324, 326 therein. A screw hole 325 is defined in a center of the press section 321.

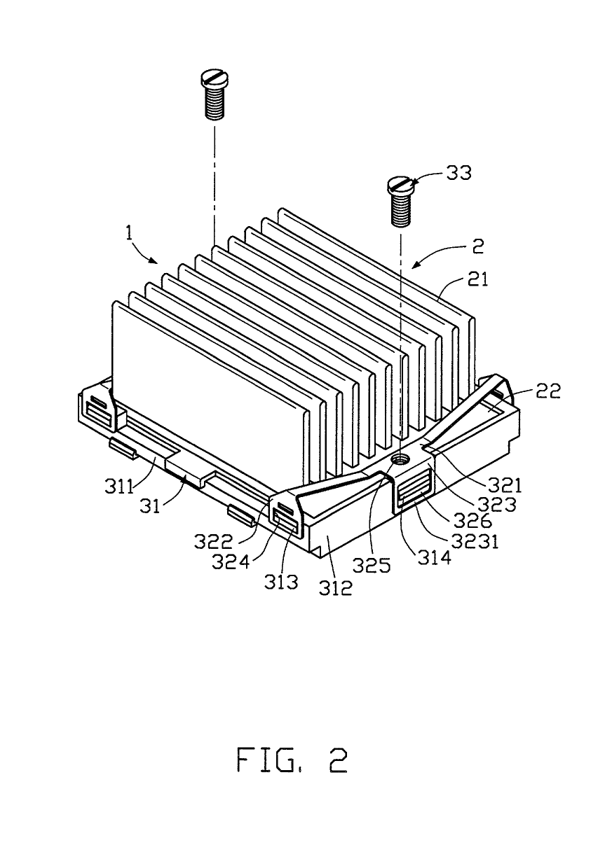

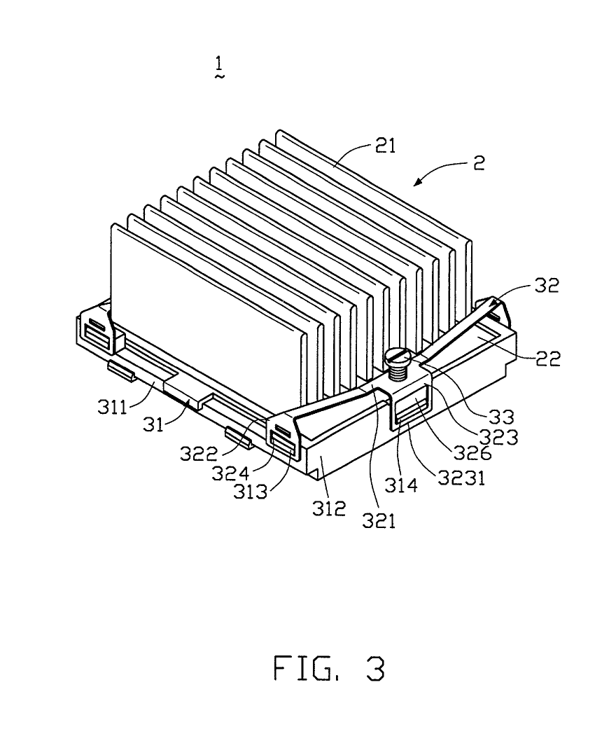

In assembly, referring to FIG. 2 and FIG. 3, after the chip unit 4 is mounted to the socket 30, the heat sink 2 is placed on the chip unit 4 with the mounting flanges located near the sidewalls of the socket 30 wherein the grooves 302 are defined. The clips 32 are then mounted to the socket 30 and the heat sink 2 by having the first retaining sections 322 buckled to the protrusions 313 and the second retaining sections 323 receiving the bulges314 of the socket 30 in which the pressing sections 321 of the clips 32 abut against a top face of the mounting flanges 22 of the heat sink 2. In order to facilitate the mounting of the clips 32 to the socket 30, the holes 326 of the second retaining sections 323 have a dimension larger than that of the bulges 314, while the holes 324 of the first retaining sections 322 have a dimension substantially the same as that of the protrusions 313. Finally, the bolts 33 are screwed into the screw holes 325 to depress the mounting flanges 22. As the bolts 33 move downwardly, the pressing sections 321 and accordingly the second retaining sections 323 move upwardly until a lower arm 3231 of each of the second retaining sections 323 fixedly engages with the bulge 314. Thus, the heat sink 2 is fixedly secured to a top face of the chip unit 4.

In the present invention, as the first retaining sections 322 have a fittingly engagement with the protrusions 313, the lower arms 3231 of the second retaining sections 323 have a firm engagement with the bulges 314 and the bolts 33 depress the heat sink 2 toward the chip unit 4, the heat sink 2 can be reliably secured to the chip unit 4 to always have an intimate engagement therewith.

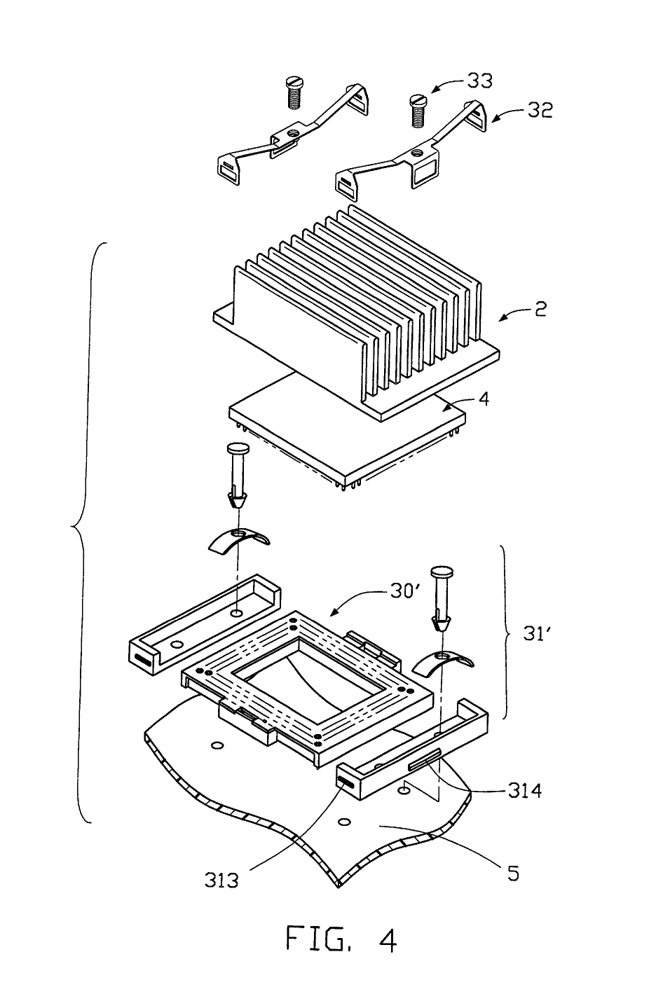

Referring to FIG. 4, in an alternative embodiment, the bulges 314 and the protrusions 313 are formed on a heat sink retention module 31′ which is separated from a socket 30′ and neighbors two lateral sides of the socket 30′ when the socket 30′ and the retention module 31′ are mounted to a motherboard 5. Such retention module 31 is well known by those skilled in the art; thus, a detailed description thereof is omitted here. The assembling of the socket 31′, the retention module 31′, the chip unit 4, the heat sink 2, the clip 32 and the bolts 33 can readily understood by the referring to the assembling of the first embodiment.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A heat sink assembly adapted for dissipating heat generated during operation of a chip unit, comprising:
a rectangular socket on which the chip unit is mounted, the socket comprising at least a mounting portion on a lateral thereof, a protrusion on each of two opposite first sides of the mounting portion, and a bulge on a second side between the first sides;
a heat sink attached on the chip unit;
at least an elongated clip having two ends fitted with the protrusions and a retaining section receiving the bulge, said retaining section having a lower arm engaging with the bulge; and
a bolt screwing through the clip and depressing the heat sink.

2. The assembly in accordance with claim 1, wherein the heat sink has a horizontal base, a plurality of heat dissipating fins upward extending from the base and a mounting flange horizontally extending from the base and located beside the fins, and wherein the bolt depresses the mounting flange.

3. The assembly in accordance with claim 1, wherein the bolt screws through a middle portion of the clip.

4. The assembly in accordance with claim 3, wherein the retaining section downwardly extends from a side of the middle portion of the clip.

5. The assembly in accordance with claim 4, wherein the retaining section has a substantially rectangular shape.

6. A heat sink assembly for dissipating heat generated during operation of a chip unit, comprising:
a rectangular socket on which the chip unit is mounted;
a heat sink retention module located beside two opposite sides of the socket, the retention module comprising at least a protrusion on each of two opposite first sides of the retaining module, and a bulge on a second sidebetween the first sides;
a heat sink attached on the chip unit;
at least an elongated clip having two ends fitted with the protrusions and a retaining section receiving the bulge, said retaining section having a lower arm engaging with the bulge; and
a bolt screwing through the clip and depressing the heat sink.

7. The assembly in accordance with claim 6, wherein the heat sink has a horizontal base, a plurality of heat dissipating fins upward extending from the base and a mounting flange horizontally extending from the base and located beside the fins, and wherein the bolt depresses the mounting flange.

8. The assembly in accordance with claim 6, wherein the bolt screws through a middle portion of the clip.

9. The assembly in accordance with claim 8, wherein the retaining section downwardly extends from a side of the middle portion of the clip.

10. The assembly in accordance with claim 9, wherein the retaining section has a substantially rectangular shape.

11. A heat sink assembly comprising:
a socket;
a chip unit positioned on the socket;
a heat sink positioned on the chip unit;
at least one mounting section located on a mother board on which the socket is mounted;
a plurality of locking projections formed on said mounting section;
the heat sink including a portion vertically aligned with said mounting section;
an elongated clip defining openings to latchably engage the corresponding locking projections, and a pole vertically moveably extending through the clip to press against the corresponding portion of the heat sink.

12. The assembly in accordance with claim 11, wherein said mounting section includes two opposite portions respectively formed on two sides of the socket.

13. The assembly in accordance with claim 11, wherein said mounting section includes two opposite portions respectively formed on two retention modules separately located by two sides of said socket.

14. The assembly in accordance with claim 11, wherein said pole is a bolt.
